(19) United States
(12) Patent Application Publication
(10) Pub. No.: US 2008/0115720 A1
(43) Pub. Date: May 22, 2008

(54) Apparatus and method for manufacturing semiconductor single crystal

(75) Inventors: Toshiaki Saishoji, Kanagawa (JP); Koichi Shimomura, Kanagawa (JP); Ryouta Suewaka, Kanagawa (JP); Daisuke Ebi, Kanagawa (JP)

Correspondence Address: WELSH & KATZ, LTD, 120 S RIVERSIDE PLAZA, 22ND FLOOR, CHICAGO, IL, 60606, US

(73) Assignee: SUMCO TECHXIV KABUSHIKI KAISHA, Kanagawa (JP)

(21) Appl. No.: 11/983,370

(22) Filed: Nov. 7, 2007

(30) Foreign Application Priority Data
Nov. 16, 2006 (JP) 2006-310321

(51) Int. Cl. C30B 15/00; H01L 21/00

(52) U.S. Cl. 117/217; 438/502; 257/E21.001

(57) ABSTRACT

A semiconductor single crystal manufacturing apparatus and method are provided which are capable of improving the speed of designing and arranging a silicon single crystal manufacturing apparatus while reducing labor by making it possible to instantaneously find optimum design values and optimum arrangement for a cooler without requiring a lot of labor or time, regardless of a housing structure of a CZ furnace, in-furnace members' configuration, and manufacturing conditions. Stable manufacture of defect-free silicon single crystals is also made possible by designing and arranging the cooler such that when a heat absorption amount of the cooler is denoted by Q and a semiconductor single crystal radius is denoted by r, the heat absorption amount of the cooler Q satisfies r²/1100≦Q≦r²/400, or alternatively Q satisfies r^{2.7}/20500≦Q≦r^{2.7}/19300.

### BACKGROUND OF THE INVENTION

1. Field of the Invention

The present invention relates to an apparatus and method for manufacturing semiconductor single crystals, and in particular to an apparatus and method for manufacturing semiconductor single crystals by pulling a semiconductor single crystal while cooling the same with the use of a cooler.

2. Description of the Related Art

A silicon single crystal is manufactured by being pulled and grown using the Czochralski (CZ) method. The grown silicon single crystal ingot is sliced into silicon wafers. A semiconductor device is fabricated through a device process forming a device layer on the surface of a silicon wafer.

However, a crystal defect referred to as “grown-in defect” (defect incurred during the crystal growth) occurs in the course of the growth of a silicon single crystal. It is believed that the grown-in defect is a secondary defect caused by a point defect incorporated into a growing crystal.

Along with recent progress of integration and refinement of semiconductor circuits, the presence of such grown-in defects has become intolerable in the vicinity of a surface layer of a silicon wafer where a device is fabricated. Thus, studies are being conducted on the possibility of producing a defect-free crystal.

In general, there are the following three types of crystal defects which may be included in a silicon single crystal and deteriorate device characteristics:

a) Void defect (V-defect) generated by aggregation of vacancies and referred to as COP (Crystal Originated Particles);

b) OSF (Oxidation Induced Stacking Fault; R-OSF); and

c) Dislocation loop clusters generated by aggregation of interstitial silicon (also known as interstitial silicon dislocation defects, or I-defects).

The V-defect may cause failure in the oxide film such as dielectric breakdown characteristics or element isolation during the semiconductor device process. The R-OSF and I-defects may adversely affect the leak current characteristics or the like.

A defect-free silicon single crystal is recognized or defined as a crystal not including or substantially not including any of the three types of defects.

It is known that the generation behaviors of the above-mentioned three types of defects significantly depend on growth conditions V/G (V denotes a growth rate, and G denotes an axial temperature gradient of the silicon single crystal near its melting point) as described for example in Non-Patent Reference 1 (Journal of Crystal Growth 59(1982)625-643).

This means that the defect distribution in the silicon single crystal is significantly affected by a growth rate or thermal environment during the growth thereof There has been arisen a growing demand for defect-free crystals in which the grown-in defect is eliminated to form a defect-free region all over the silicon wafer, and thus many proposals have been made on manufacturing conditions for controlling the growth rate or temperature distribution.

On the other hand, there has conventionally been practiced a silicon single crystal manufacturing method in which a cooler is arranged around a silicon single crystal to be pulled from a melt in a CZ furnace, and the silicon single crystal is pulled while being cooled by the cooler.

The cooler acts to cool the silicon single crystal and absorb latent heat of solidification when the silicon single crystal is solidified. Thus, the period of time required for the growth of the silicon single crystal can be shortened significantly by the provision of the cooler. Further, the shortening of the growth time of the silicon single crystal prevents the crumbling of the single crystal otherwise caused by deterioration of the furnace environment due to evaporated substances from the silicon melt or deterioration of the quartz crucible. Accordingly, the productivity of silicon single crystals can be improved by increasing the growth rate of the silicon single crystals. However, excessive increase of the growth rate of the silicon single crystal may hinder stable single crystallization or even disable the single crystallization.

Patent Reference 1 (Japanese Patent Application Laid-Open Patent Publication No. 2000-281478) describes an invention in which a cooler is arranged in a CZ furnace such that the distance between the lower end of the cooler and the melt surface is 150 mm or less, and the pulling rate of the pulling apparatus to pull a silicon ingot and the heater output are adjusted so as to attain a set value for the growth condition V/G (V denotes a growth rate, and G denotes an axial temperature gradient of the silicon single crystal near its melting point).

Further, Patent Reference 2 (Japanese Patent Application Laid-Open Patent Publication No. 2005-247629) describes an invention in which a cooler the surface of which is blackened is arranged in a CZ furnace to reduce the variation in heat absorption from a silicon single crystal due to individual differences among the coolers.

Patent Reference 3 (Japanese Patent Application Laid-Open Patent Publication No. 2001-220289) describes an invention in which a cooler arranged in a CZ furnace is designed such that the inner diameter and the length of the cooler, and the distance from the melt surface to the cooler are proportional to the diameter of a silicon single crystal.

Patent Reference 4 (Japanese Patent Application Laid-Open Patent Publication No. 2002-255682) describes an invention relating to configuration of a water cooling type cooler, in which a cooling water passage is arranged spirally around a silicon single crystal.

In the CZ furnace, there are various other members such as a heat shielding plate in addition to the cooler. The performance of the cooler to cool a silicon single crystal is affected by a housing structure of the CZ furnace, configuration of the in-furnace members, and various manufacturing conditions such as power of a heater. Accordingly, even if the cooler is designed and arranged as described in the Patent References 1 to 4, it might be impossible to obtain a sufficient cooling performance if the housing structure of the CZ furnace, the configurations of the in-furnace members or the manufacturing conditions are different from what are assumed in the Patent References 1 to 4. If sufficient cooling performance cannot be obtained, it will be impossible to achieve a desired growth rate or productivity, or will disable the single crystallization. As a result, it becomes necessary to perform many trial-and-error tests to find optimum design values and optimum arrangement for the cooler every time there occurs any alteration in the housing structure of the CZ furnace, the configurations of the in-furnace members, or the manufacturing conditions. In other words, a great deal of labor and time are required to find optimum design values and optimum arrangement for the cooler.

Furthermore, none of the Patent References 1 to 4 above mentions at all what relation exists between the cooler performance and the generation behaviors of the three types of defects described above. In other words, none of them explains at all how the cooler should be designed and arranged to stably produce defect-free silicon single crystals.

### SUMMARY OF THE INVENTION

The present invention has been made in view of such circumstances, and a first object of the invention is to improve the speed of designing and arranging a silicon single crystal manufacturing apparatus and to minimize the labor by making it possible to instantaneously find optimum design values and optimum arrangement for the cooler without requiring a lot of labor or time regardless of the housing structure of the CZ furnace, configurations of the in-furnace members, and the manufacturing conditions.

In addition to the first object, the present invention has a second object to determine what relation exists between the generation behaviors of the three types of defects and the cooler performance, and to make it possible to design and arrange the cooler so as to enable stable manufacture of defect-free silicon single crystals.

A first aspect of the invention provides a semiconductor single crystal manufacturing apparatus having a cooler arranged to surround a semiconductor single crystal being pulled from a melt within a furnace so that the semiconductor single crystal is manufactured by being pulled while being cooled with the cooler. This semiconductor single crystal manufacturing apparatus is characterized in that when a heat absorption amount of the cooler is denoted by Q (kW) and a radius of the semiconductor single crystal is denoted by r (mm), the cooler is designed and arranged so as to satisfy the condition r²/1100≦Q≦r²/400.

A second aspect of the invention provides a semiconductor single crystal manufacturing method for manufacturing a semiconductor single crystal by arranging a cooler within a furnace to surround a semiconductor single crystal being pulled from a melt, and pulling the semiconductor single crystal while cooling the same with the cooler.

This semiconductor single crystal manufacturing method is characterized in that when a heat absorption amount of the cooler is denoted by Q (kW) and a radius of the semiconductor single crystal is denoted by r (mm), the cooler is designed and arranged so as to satisfy the condition r²/1100≦Q≦r²/400.

A third aspect of the invention provides a semiconductor single crystal manufacturing apparatus having a cooler arranged to surround a semiconductor single crystal being pulled from a melt within a furnace so that the semiconductor single crystal is manufactured by being pulled while being cooled with the cooler. This semiconductor single crystal manufacturing apparatus is characterized in that when a heat absorption amount of the cooler is denoted by Q (kW) and a radius of the semiconductor single crystal is denoted by r (mm), the cooler is designed and arranged so as to satisfy the condition r^{2.7}/20500≦Q≦r^{2.7}/19300.

A fourth aspect of the invention provides a semiconductor single crystal manufacturing method for manufacturing a semiconductor single crystal by arranging a cooler within a furnace to surround a semiconductor single crystal being pulled from a melt, and pulling the semiconductor single crystal while cooling the same with the cooler. This semiconductor single crystal manufacturing method is characterized in that when a heat absorption amount of the cooler is denoted by Q (kW) and a radius of the semiconductor single crystal is denoted by r (mm), the cooler is designed and arranged so as to satisfy the condition r^{2.7}/20500≦Q≦r^{2.7}/19300.

According to the first and second aspects of the invention, a silicon single crystal 10 is manufactured by designing and arranging a cooler 20 such that when a heat absorption amount of the cooler is denoted by Q, and a radius of the semiconductor single crystal is denoted by r, the following expression is satisfied

r²/1100≦Q≦r²/400 (4)

whereby the growth rate V can be improved and yet the single crystallization remains possible.

The range represented by the expression (4) corresponds to a range, whose upper limit is defined by the line L1u and whose lower limit is defined by the line L1L. Therefore, the cooler 20 should be designed and arranged in the CZ furnace 2 such that its absorption amount Q is contained in this range.

More specifically, once a radius r of a silicon single crystal 10 to be manufactured is determined, a cooler 20 is designed such that the heat absorption amount Q is contained in the range represented by the expression (4) above. When arranging the cooler 20 within a CZ furnace 2, the distance P from a heat shielding plate 8 to the lower end of the cooler 20 (see FIG. 1) and the gap D between the lower end of the heat shielding plate 8 and the melt surface 5a are adjusted such that the heat absorption amount Q is contained in the range represented by the expression (4) above.

According to the first and second aspects of the invention, it is made possible to instantaneously find optimum design values and optimum arrangement for the cooler 20 without the need of a lot of labor or time, regardless of a housing structure of the CZ furnace 2, configurations of in-furnace members, and manufacturing conditions.

Therefore, the speed of designing and arranging the silicon single crystal manufacturing apparatus can be improved, and the labor can be reduced.

According to the third and fourth aspects of the invention, stable manufacture of a defect-free silicon single crystal 10 is advantageously made possible by designing and arranging the cooler 20 to satisfy the following expression (7) when a heat absorption amount of the cooler 20 is denoted by Q, and a radius of the semiconductor single crystal is denoted by r.

r^{2.7}/20500≦Q≦r^{2.7}/19300 (7)

Referring to the relation between the crystal radius r and the heat absorption amount Q shown in FIG. 10, the range represented by the expression (7) above is a range whose upper limit defined is by the line L2u and whose lower limit is defined by the line L2L. Accordingly, the cooler 20 should be designed and arranged in the CZ furnace 2 such that the heat absorption amount Q is contained in this range.

Specifically, once a radius r of a silicon single crystal 10 to be manufactured is determined, the cooler 20 is designed such that its heat absorption amount Q is contained in the range represented by the expression (7) above. When arranging the cooler 20 within the CZ furnace 2, the distance P from a heat shielding plate 8 to the lower end of the cooler 20 (see FIG. 1) and the gap D between the lower edge of the heat shielding plate 8 and melt surface 5a are adjusted so that an actual heat absorption amount Q is contained in the range represented by the expression (7) above.

As shown in FIG. 10, the range represented by the expression (7) contains the region represented by the expression (4) above according to the first and second aspects of the invention. It is therefore obvious that the advantageous effects of the first example that the growth rate V can be improved while ensuring the single crystallization are also realized in the range represented by the expression (7).

Consequently, according to the third and fourth aspects of the invention, like the first and second aspects of the invention, it is made possible to instantaneously find optimum design values and optimum arrangement for the cooler 20 without the need of a lot of labor or time, regardless of a housing structure of the CZ furnace 2, configurations of in-furnace members, and manufacturing conditions. Therefore, the speed of designing and arranging the silicon single crystal manufacturing apparatus can be improved, and the labor can be reduced. Further, according to the third and fourth aspects of the invention, the cooler 20 can be designed and arranged to ensure stable manufacture of defect-free silicon single crystals.

### BRIEF EXPLANATION OF THE DRAWINGS

FIG. 1 is a diagram schematically showing a configuration of a single crystal pulling apparatus according to a preferred embodiment of the present invention;

FIG. 2 is a block diagram showing a cooling water circuit of a water cooling type cooler used in examples;

FIG. 3 is a diagram for explaining a first example, and is a table comparing experiment examples with comparative examples;

FIG. 4 is a diagram for explaining the first example, and is a graph illustrating relation between a heat absorption amount and a growth rate ratio for each of crystal radii;

FIGS. 5A and 5B are diagrams illustrating relation between a growth rate V and defect generation distribution on the surface of a silicon single crystal (silicon wafer surface);

FIG. 6 is a diagram for explaining a second example, and is a table showing a gap between the lower edge of a heat shielding plate and the melt surface, a cooling water flow rate, inlet-side cooling water temperature, outlet-side cooling water temperature, a heat absorption amount, and tolerance in growth rate observed for each of experiment examples when the heat absorption amount of the cooler was variously changed with respect to a silicon single crystal having a radius of 100 mm;

FIG. 7 is a graph associated with FIG. 6 and showing relation between the heat absorption amount of the cooler and the tolerance in growth rate;

FIG. 8 is a diagram for explaining the second example, and is a table showing a gap between the lower edge of a heat shielding plate and the melt surface, a cooling water flow rate, inlet-side cooling water temperature, outlet-side cooling water temperature, a heat absorption amount, and tolerance in growth rate observed for each of experiment examples when the heat absorption amount of the cooler was variously changed with respect to a silicon single crystal having a radius of 150 mm;

FIG. 9 is a graph associated with FIG. 8 and showing relation between the heat absorption amount of the cooler and the tolerance in growth rate; and

FIG. 10 is a graph showing relation between the crystal radius and the heat absorption amount.

### DETAILED DESCRIPTION OF THE INVENTION

Preferred embodiments of an apparatus and a method for manufacturing semiconductor single crystals according to the present invention will be described with reference to the accompanying drawings.

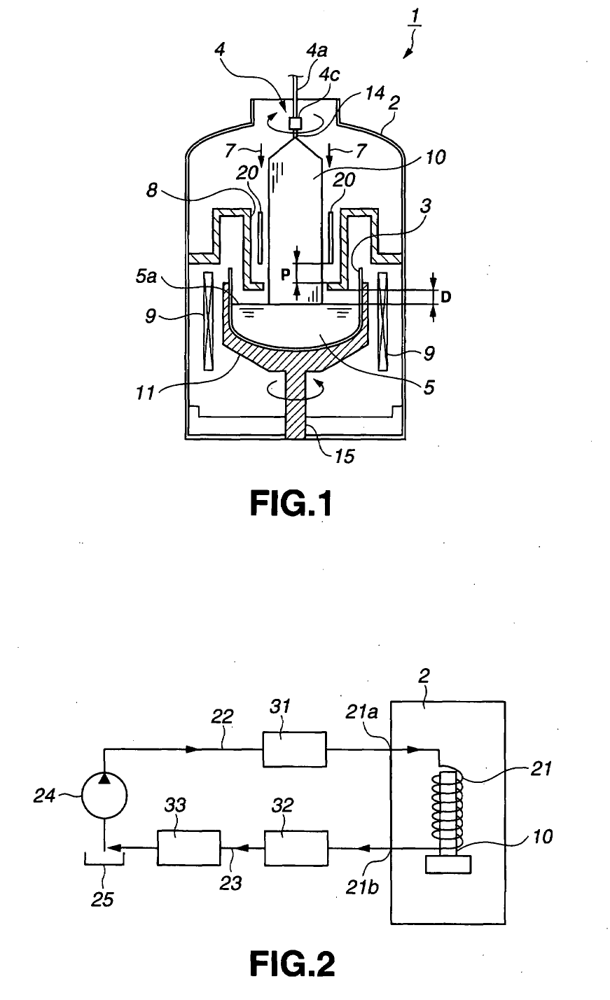

FIG. 1 is a side view showing an example configuration of a silicon single crystal manufacturing apparatus used in the embodiment.

As shown in FIG. 1, a single crystal pulling apparatus 1 according to the embodiment has a CZ furnace (chamber) 2 serving as a single crystal pulling vessel.

A quartz crucible 3 is provided in the CZ furnace 2 to contain a molten polycrystalline silicon material as melt 5. The outside of the quartz crucible 3 is covered with a graphite crucible 11. A heater 9 is arranged to surround the quartz crucible 3, for heating and melting the polycrystalline silicon material in the quartz crucible 3. The heater 9 is formed into a cylindrical shape. The output power (kW) of the heater 9 is controlled to adjust the amount of heat applied to the melt 5. For example, temperature of the melt 5 is detected, and the detected temperature is used as a feedback amount to control the output of the heater 9 so that the temperature of the melt 5 becomes a target temperature.

A pulling mechanism 4 is provided above the quartz crucible 3. The pulling mechanism 4 includes a pulling shaft 4a and a seed chuck 4c provided at the distal end of the pulling shaft 4a. The seed chuck 4c holds a seed crystal 14.

The polycrystalline silicon (Si) is heated and molten in the quartz crucible 3. Once the temperature of the melt 5 is stabilized, the pulling mechanism 4 is activated to pull a silicon single crystal 10 from the melt 5. Specifically, the pulling shaft 4a is lowered and the seed crystal 14 held by the seed chuck 4c at the distal end of the pulling shaft 4a is immersed in the melt 5. After the seed crystal 14 is wetted with the melt 5, the pulling shaft 4a is raised. The silicon single crystal 10 grows as the seed crystal 14 held by the seed chuck 4c is raised.

The quartz crucible 3 is rotated by a rotating shaft 15 during the pulling. The pulling shaft 4a of the pulling mechanism 4 is rotated in the opposite direction to or in the same direction as the rotating shaft 15.

The rotating shaft 15 can be driven in a vertical direction to move the quartz crucible 3 up and down to a desired crucible position.

The inside of the CZ furnace 2 is maintained at a vacuum (e.g. about several tens of Torr) by shielding the inside of the CZ furnace 2 from outside air. Specifically, argon gas 7 as inert gas is supplied into the CZ furnace and discharged by a pump through an exhaust port of the CZ furnace 2. This reduces the pressure in the furnace 2 to a predetermined pressure.

Various vaporized substances are produced in the inside of the CZ furnace 2 during a single crystal pulling process (one batch). Therefore, the argon gas 7 is supplied into the CZ furnace 2 and discharged together with the vaporized substances out of the CZ furnace 2 to clean away the vaporized substances from the CZ furnace 2. The supply flow rate of the argon gas 7 is set for each step in one batch.

The melt 5 is decreased as the silicon single crystal 10 is pulled. As the melt 5 is decreased, the contact area between the melt 5 and the quartz crucible 3 varies, which changes the amount of oxygen dissolved from the quartz crucible 3. This change affects distribution of oxygen concentration in the silicon single crystal 10 being pulled.

A heat shield plate 8 (gas rectifying tube) is provided above the quartz crucible 3 to surround the silicon single crystal 10. The heat shield plate 8 guides the argon gas 7 supplied, as the carrier gas, from above into the CZ furnace 2 to a central part in the melt surface 5a, and further guides the same to the periphery of the melt surface 5a, passing over the melt surface 5a. The argon gas 7 is then discharged together with evaporated gas from the melt 5 through an exhaust port provided in a lower part of the CZ furnace 2. In this manner, the gas flow speed over the melt surface can be stabilized, and oxygen evaporated from the melt 5 can be kept in a stable state.

The heat shielding plate 8 thermally insulates and shields the seed crystal 14 and the silicon single crystal 10 grown from the seed crystal 14 from radiant heat generated by high-temperature components such as the quartz crucible 3, the melt 5, and the main heater 9. Further, the heat shield plate 8 prevents an impurity generated within the furnace (e.g. silicon oxide) from adhering on the silicon single crystal 10 and inhibiting the growth of the single crystal. The size of a gap D between the lower edge of the heat shield plate 8 and the melt surface 5a can be adjusted by raising or lowering the rotating shaft 15 to change the position of the quartz crucible 3 in the vertical direction. The gap D may be adjusted by vertically moving the heat shield plate 8 by means of an elevating device.

A cooler 20 is arranged to surround the silicon single crystal 10 pulled from the melt 5. The cooler 20 is arranged on the inner side of the heat shielding plate 8. The cooler 20 is provided for cooling the silicon single crystal 10 while pulling the same.

It is assumed in the first example that the cooler 20 which is of a water cooling type is arranged in the CZ furnace 2.

FIG. 2 is a block diagram showing a cooling water circuit of the cooler 20.

The cooler 20 is for example formed as a pipe 21 which is formed spirally to surround a silicon single crystal (ingot) 10 being pulled. An inlet 21a of the pipe 21 is connected to a supply pipe 22 provided outside of the CZ furnace 2. An outlet 21b of the pipe 21 is connected to a return pipe 23 provided outside of the CZ furnace 2. A discharge port of the pump 24 communicates with the supply pipe 22. A tank 25 communicates with a return pipe 23. Upon activation of the pump 24, cooling water is fed under pressure via the supply pipe 22 and the inlet 21a of the pipe 21 and flows through the pipe 21 at a predetermined flow rate. Thus, heat exchange is performed between the cooling water flowing in the pipe 21 and heat sources including the silicon single crystal 10 present around the pipe 21, whereby heat emitted from the heat sources including the silicon single crystal 10 is absorbed by the cooling water. The cooling water after absorbing the heat is discharged from the outlet 21b of the pipe 21 and returned to the tank 25 through the return pipe 23. A pump 24 pumps the cooling water from the tank 25 and again pressure-feed the cooling water. The cooling water is circulated in the cooler 20 as described above to thereby cool the silicon single crystal 10 being pulled. It should be noted that a heat exchanger for allowing the cooling water to release the absorbed heat is omitted from FIG. 2.

A heat absorption amount Q (kW) of the cooler 20 can be represented by the following expression (1) when temperature (° C.) of the cooling water at the outlet 21b of the pipe 21 is denoted by Tout, temperature (° C.) of the cooling water at the inlet 21a of the pipe 21 is denoted by Tin, flow rate (1/min) of the cooling water is denoted by f, and specific heat of water (about 0.06976) is denoted by c.

Q=(Tout−Tin)×f×c (1)

A heat absorption amount Q of the cooler 20 can be obtained in the following manner, for example. The supply pipe 22 is provided with a temperature measuring sensor 31 and the return pipe 23 is provided with a temperature measuring sensor 32 and a flowmeter 33 as shown in FIG. 2 so that the inlet-side cooling water temperature Tin is measured with the temperature measuring sensor 31, the outlet-side cooling water temperature Tout is measured with the temperature measuring sensor 32, and the cooling water flow rate f is measured with the flowmeter 33. The inlet-side cooling water temperature Tin and the outlet-side cooling water temperature Tout thus obtained are substituted into the expression (1) above to calculate the heat absorption amount Q.

The cooler 20 functions to cool the silicon single crystal 10 and absorb latent heat of solidification generated during solidification of the silicon single crystal 10. Therefore, the provision of the cooler 20 makes it possible to substantially shorten the period of time required for growth of the silicon single crystal 10. Further, the shortening of the growth time of the silicon single crystal 10 prevents the crumbling of single crystals otherwise caused by deterioration of the furnace environment due to evaporated substances from the silicon melt 5, or by deterioration of the quartz crucible 3. Accordingly, the productivity of the silicon single crystal 10 can be improved by increasing the growth rate V of the silicon single crystal 10. However, excessive increase of the growth rate V of the silicon single crystal 10 will hinder stable single crystallization or even disable the single crystallization.

### FIRST EXAMPLE

Experiments were conducted to find conditions under which the growth rate could be improved and yet the single crystallization was possible.

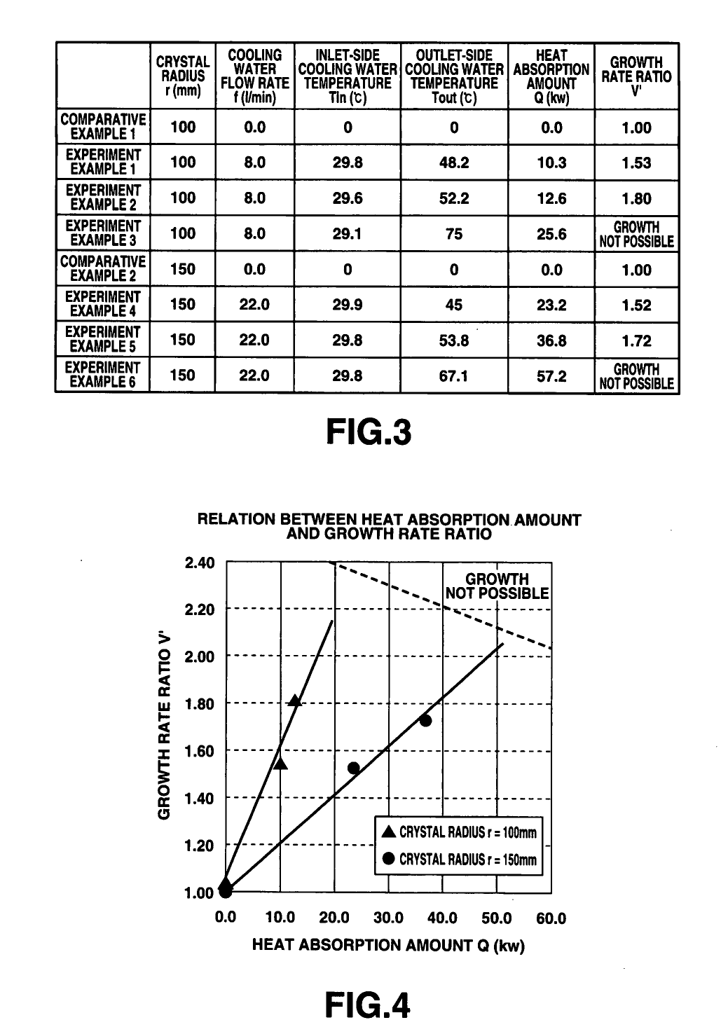

In this example, experiments were conducted on the assumption that certain relation would be established between a heat absorption amount Q (kW) of the cooler 20 and a size or a radius r (mm) of a silicon single crystal 10 to be manufactured. As a result, the experiment results as shown in FIG. 3 and FIG. 4 were obtained.

A single crystal pulling apparatus having the same configuration as the single crystal pulling apparatus 1 shown in FIG. 1 but having no cooler 20 was used as a comparative example. Experiments of the comparative example were conducted for each of silicon single crystals 10 having a radius r of 100 mm and a radius r of 150 mm.

FIG. 3 is a table comparing the comparative examples with the experiment examples. Crystal radius r, cooling water flow rate f, inlet-side cooling water temperature Tin, outlet-side cooling water temperature Tout, heat absorption amount Q, and growth rate ratio V′ are shown for each of the comparative examples and experiment examples.

In FIG. 3, the comparative example for the silicon single crystal 10 having a radius r of 100 mm is indicated as “comparative example 1”. The experiment results for the silicon single crystal 10 having a radius r of 100 mm are indicated as “experiment example 1”, “experiment example 2”, and “experiment example 3”. The comparative example for the silicon single crystal 10 having a radius r of 150 mm is indicated as “comparative example 2”, and the experiment results for the silicon single crystal 10 having a radius r of 150 mm are indicated as “experiment example 4”, “experiment example 5”, and “experiment example 6”.

FIG. 4 is a graph illustrating relation between the heat absorption amount Q and the growth rate ratio V′ for each of the crystal radii r, namely for the radius of 100 mm and the radius of 150 mm.

The heat absorption amount Q of the cooler 20 was variously changed and compared with the heat absorption amount Q of the comparative examples. The heat absorption amount Q of the comparative example was defined as zero since no cooler 20 was provided. Also, the growth rates V obtained when the heat absorption amount Q of the cooler 20 was varied were compared with the growth rate V of the comparative examples.

In FIGS. 3 and 4, the growth rate V of the comparative examples is defined as one (1), and growth rates V obtained when the heat absorption amount Q of the cooler 20 was variously changed are indicated by ratios relative to one. In other words, they are indicated by a growth rate ratio V′. Those experiment examples in which single crystallization was disabled even if the growth rate ratio V′ exhibited a large value were evaluated as “growth not possible”.

The cooler 20 was designed such that the cooling water flow rate f, the inlet-side cooling water temperature Tin, and the outlet-side cooling water temperature Tout respectively took different values to vary the heat absorption amount Q, and arranged within the CZ furnace 2.

The evaluation that “improvement in the growth rate was observed” was made when a growth rate V 1.5 or more times higher than the growth rate V of the comparative example was obtained, that is, when the growth rate ratio V′ was 1.5 or higher.

As seen from FIGS. 3 and 4, for the silicon single crystal 10 having a radius r of 100 mm, the experiment example 1 and the experiment example 2 exhibited the results that the growth rate ratio V′ was 1.5 or higher and yet the crystal growth was possible. The heat absorption amount Q and growth rate ratio V′ of the experiment example 1 were 10.3 and 1.53, respectively. The heat absorption amount Q and growth rate ratio V′ of the experiment example 2 were 12.6 and 1.80, respectively.

The experiment example 3 exhibited the result of “growth not possible”. The heat absorption amount Q of the experiment example 3 was 25.6.

Consequently, when the single crystal silicon 10 has a radius r of 100 mm, the following expression (2) is established as conditions for obtaining the result that the growth rate ratio V′ is 1.5 or higher and yet the crystal growth is possible.

r²/1100 (=9.09)≦Q(=10.3 in experiment example 1, and 12.6 in experiment example 2)≦r²/400 (=25≦25.6 in experiment example 3) (2)

Further, as seen from FIGS. 3 and 4, when the silicon single crystal 10 has a radius r of 150 mm, the experiment example 4 and the experiment example 5 exhibited the results that the growth rate ratio V′ was 1.5 or higher and yet the crystal growth was possible. The heat absorption amount Q and the growth rate ratio V′ of the experiment example 4 were 23.2 and 1.52, respectively. The heat absorption amount Q and the growth rate ratio V′ of the experiment example 5 were 36.8 and 1.72, respectively.

The experiment example 6 exhibited the result of “growth not possible”. The heat absorption amount Q of the experiment example 6 was 57.2.

Consequently, when the single crystal silicon 10 has a radius r of 150 mm, the following expression (3) is established as conditions for obtaining the result that the growth rate ratio V′ is 1.5 or higher and yet the crystal growth is possible.

r²/1100 (=20.45)≦Q(=23.2 in experiment example 4 and 36.8 in experiment example 5)≦r²/400(=56.3≦57.2 in experiment example 6) (3)

It was found based on the expressions (2) and (3) above that the growth rate V could be improved and yet single crystallization would be possible if the cooler 20 was designed and arranged so that the silicon single crystal 10 was manufactured to satisfy the following expression (4) when the heat absorption amount of the cooler 20 is denoted by Q, and the radius of the semiconductor single crystal is denoted by r.

r²/1100≦Q≦r²/400 (4)

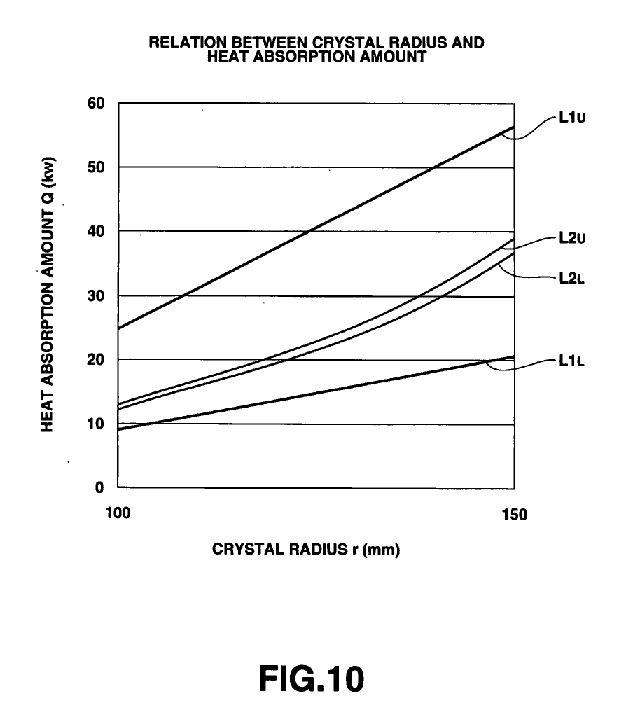

FIG. 10 illustrates relation between the crystal radius r and the heat absorption amount Q. The range represented by the expression (4) above has an upper limit defined by a line L1u and a lower limit defined by a line L1L. Therefore, the cooler 20 should be designed and arranged in the CZ furnace 2 such that the heat absorption amount Q is contained in this range.

This means that, once the radius r of the silicon single crystal 10 to be manufactured is determined, the cooler 20 is designed such that the heat absorption amount Q is contained in the range satisfying the expression (4) above. When the cooler 20 is arranged within the CZ furnace 2, the distance P from the heat shielding plate 8 to the lower end of the cooler 20 (see FIG. 1) and the gap D between the lower edge of the heat shielding plate 8 and the melt surface 5a should be adjusted such that the actual heat absorption amount Q is contained in the range satisfying the expression (4) above.

According to the first example as described in the above, it is possible to instantaneously find optimum design values and optimum arrangement for the cooler 20 without requiring a lot of labor or time, regardless of the housing structure of the CZ furnace 2, configuration of the in-furnace members, and manufacturing conditions. Therefore, the speed for designing and arrangement of the silicon single crystal manufacturing apparatus can be improved, while the labor required can be reduced.

### SECOND EXAMPLE

It is known, as described above, that the generation behaviors of the three types of defects, namely V-defect, R-OSF, and I-defect vary depending on the growth conditions such as the growth rate V of silicon single crystal 10.

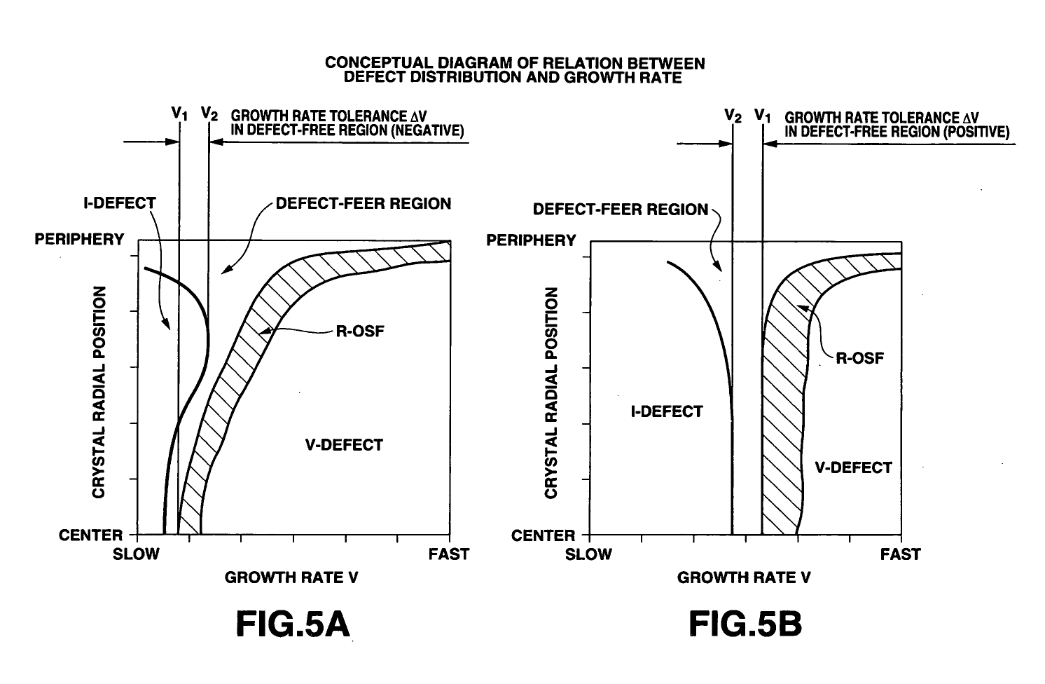

Specifically, the distribution of the three types of defects as viewed in a surface of a silicon wafer cut out vertically to the single crystal pulling axis is significantly affected by the growth rate and the thermal environment during the growth. FIGS. 5A and 5B are diagrams illustrating relation between the defect distribution and the pulling rate for two types of crystals having different crystal temperature distributions (furnace temperature environments), respectively. As seen from FIGS. 5A and 5B, there arise two different cases, that is, a case in which no defect-free region is present in the whole surface of the silicon wafer (FIG. 5A), and a case in which the defect-free region is formed in the whole surface of the wafer by controlling the growth rate V (FIG. 5B).

However, it has not conventionally been known how the generation behaviors of the three types of defects are related with the performance of the cooler 20.

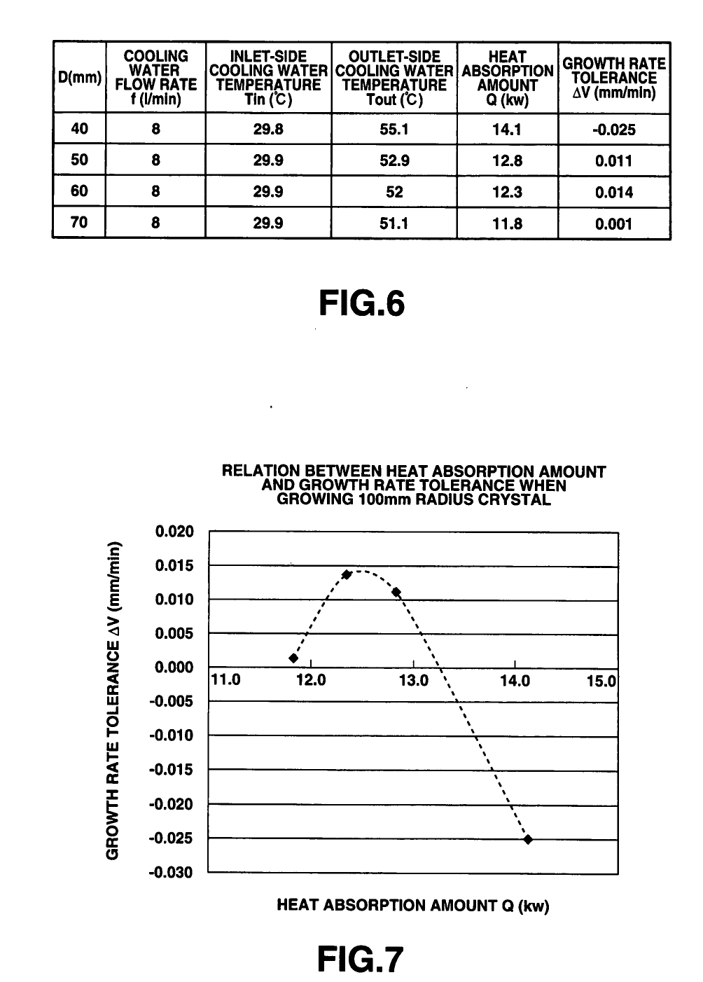

Therefore, in the present example, experiments were conducted on the assumption that an indicator, or a heat absorption amount Q of the cooler 20 affects the generation behaviors of the three types of defects described above. The experiments were conducted to find conditions required for manufacturing a defect-free silicon single crystal 10 in a stable manner. Experiment results thus obtained are shown in FIGS. 6 to 9.

The experiments were performed on silicon single crystals 10 having radii r of 100 mm and 150 mm, respectively. It was found that as the heat absorption amount Q of the cooler 20 was changed variously, the growth rate tolerance ΔV varied in accordance therewith.

Definition of the growth rate tolerance ΔV will be explained using FIGS. 5A and 5B.

FIGS. 5A and 5B both illustrate relation between distribution of defects generated in the silicon single crystal surface (silicon wafer surface) and the growth rate V

In FIGS. 5A and 5B, the horizontal axis represents the growth rate V, and the vertical axis represents the position in the crystal radius from the center to the outer periphery (edge) of the silicon single crystal 10.

The following matters are commonly known, as also seen from FIGS. 5A and 5B.

i) When the growth rate V is high, the void-type point defects become excessive and only void defects, or V-defects occur in the silicon single crystal 10.

ii) When the growth rate V is reduced, OSF, or R-OSF will occur in a ring shape near the periphery of the silicon single crystal 10, and V-defects (void defects) are present in the inside of the R-OSF.

iii) When the growth rate V is reduced further, the radius of the ring-shaped OSF (R-OSF) is reduced, and a region including no defects, namely a defect-free region is formed on the outside of the ring-shaped OSF, while V-defects (void defects) are present in the inside of the R-OSF.

iV) When the growth rate V is reduced still further, dislocation loop clusters, or I-defects are present all over the silicon single crystal 10.

It is believed that the phenomena as described above occur because, along with the reduction of the growth rate V, the state of the silicon single crystal 10 shifts from a state in which void-type point defects are excessive to a state in which interstitial point defects are excessive.

Thus, it is believed that the V-defect region, the R-OSF, the defect-free region, and I-defect region are distributed in this order as the growth rate V of the silicon single crystal 10 is reduced, and the defect-free region is present between the R-OSF and the I-defect region.

Therefore, the minimum of the growth rate V corresponding to the boundary between the R-OSF and the defect-free region is defined as V1, the maximum of the growth rate V corresponding to the boundary between the I defect region and the defect-free region is defined as V2, and the growth rate tolerance ΔV is defined as V1-V2.

As seen from FIG. 5A, if the growth rate tolerance ΔV (=V1−V2) is negative, there is no defect-free region in any of the positions in the radial direction of the silicon single crystal surface, namely in the entire silicon wafer surface. In contrast, as seen from FIG. 5B, when the growth rate tolerance ΔV (=V1−V2) is positive, the defect-free region is present in all the positions in the radial direction of the silicon single crystal surface, that is, over the entire silicon wafer surface. However, even if the growth rate tolerance ΔV (=V1−V2) is positive, defects may occur due to even slight change in the manufacturing conditions or the like if the tolerance ΔV is small. In this case, it is difficult to provide a silicon single crystal 10 having a defect-free region over the whole silicon single crystal surface. Therefore, it is supposed that growth rate tolerance ΔV must be a predetermined threshold value or greater. It is believed that when the single crystal is produced at a growth rate around 0.5 (mm/min), the threshold value must be at least 0.005 (mm/min) corresponding to 1% of the growth rate.

In conclusion, the requirement for stable manufacture of defect-free silicon single crystals 10 is that the growth rate tolerance ΔV (=V1−V2) is a positive value which is greater than the threshold value of 0.005 (mm/min).

On the basis of description above, experiment results shown in FIGS. 6 to 9 will be explained.

FIGS. 6 and 7 show experiment results for the silicon single crystal 10 having a radius r of 100 mm.

FIG. 6 is a table indicating values of the gap D between the lower end of the heat shielding plate 8 and the melt surface 5a, the cooling water flow rate f, the inlet-side cooling water temperature Tin, the outlet-side cooling water temperature Tout, the heat absorption amount Q, and the growth rate tolerance ΔV, which were obtained when the heat absorption amount Q of the cooler 20 was changed for each of experiment examples.

FIG. 7 is a graph associated with FIG. 6, illustrating relation between the heat absorption amount Q of the cooler 20 and the growth rate tolerance ΔV.

The experiments were conducted by changing the gap D to 40 mm, 50 mm, 60 mm, and 70 mm, changing the outlet-side cooling water temperature Tout to 55.1, 52.9, 52, and 51.1° C., and changing the heat absorption amount Q to 14.1, 12.8, 12.3, and 11.8 (kW). On the other hand, the cooling water flow rate f was fixed to 8 (1/min), and the inlet-side cooling water temperature Tin was substantially fixed within a range of 29.8 to 29.9° C. As a result, the growth rate tolerance ΔV was varied to −0.025, 0.011, 0.014, and 0.001 (mm/min). The distance P from the heat shielding plate 8 to the lower end of the cooler 20 was set to 30 mm.

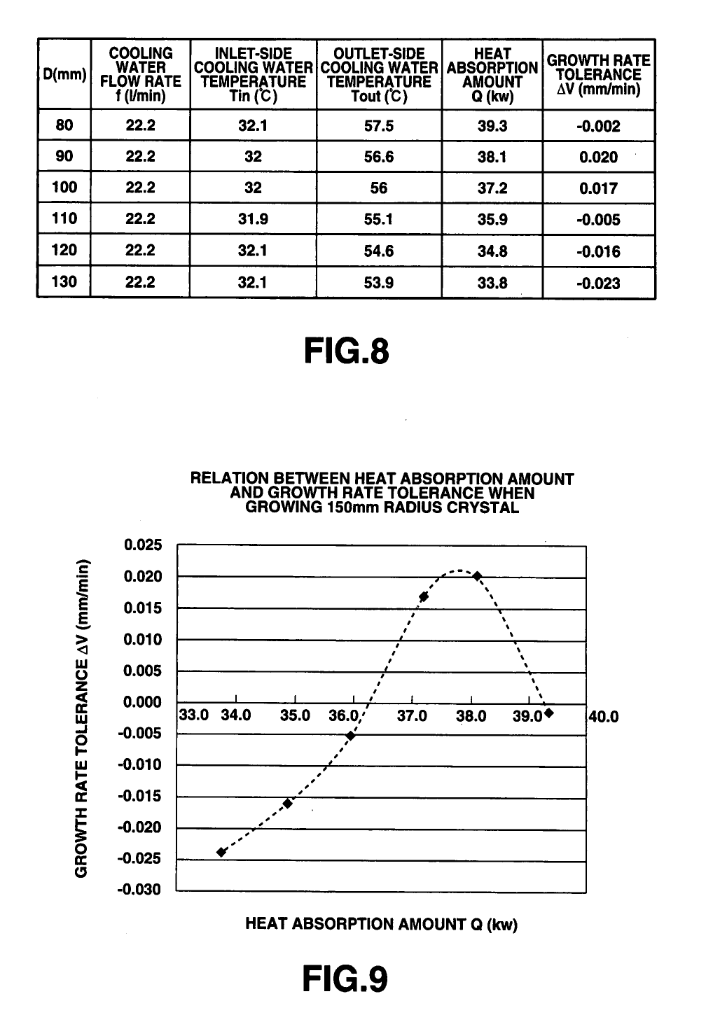

FIGS. 8 and 9 show experiment results for the silicon single crystal 10 having a radius r of 150 mm. FIG. 8 is a table like FIG. 6 described above, and FIG. 9 is a graph illustrating the relation like FIG. 7.

The experiment was conducted by changing the gap D to 80 mm, 90 mm, 100 mm, 110 mm, 120 mm, and 130 mm, changing the outlet-side cooling water temperature Tout to 57.5, 56.6, 56, 55.1, 54.6, and 53.9° C., and changing the heat absorption amount Q to 39.3, 38.1, 37.2, 35.9, 34.8, and 33.8 (kW). On the other hand, the cooling water flow rate f was fixed to 22.2 (1/min), and the inlet-side cooling water temperature Tin was substantially fixed within a range of 31.9 to 32.1° C. Additionally, a horizontal magnetic field having an intensity of 3000 G was applied. As a result, the growth rate tolerance ΔV was varied to −0.002, 0.020, 0.017, −0.005, −0.016, and −0.023 (mm/min). The distance P from the heat shielding plate 8 to the lower end of the cooler 20 was set to 120 mm.

It was thus found that the growth rate tolerance ΔV was varied by changing the heat absorption amount Q of the cooler 20. Specifically, it was found that as the heat absorption amount Q of the cooler 20 was changed, the defect generation distribution in the silicon single crystal surface varied as illustrated in FIGS. 5A and 5B, while the growth rate tolerance ΔV took negative and positive values.

As seen from FIG. 7, it is supposed that when the silicon single crystal 10 has a radius r of 100 mm, the requirement for stable manufacture of defect-free silicon single crystals 10 is that the growth rate tolerance ΔV (=V1−V2) takes a positive value which is equal to greater than the threshold value of 0.005 (mm/min), and this requirement is satisfied when the heat absorption amount Q of the cooler 20 is in the range 12(kW) ≦Q≦13.1 (kW). When the condition for the radius r of the silicon single crystal 10 is applied thereto, the following relation should be established.

r^{2.7}/20500(=12.25)≦Q≦r^{2.7}/19300(=13) (5)

Likewise, as seen from FIG. 9, it is supposed that when the silicon single crystal 10 has a radius r of 150 mm, the requirement for stable manufacture of defect-free silicon single crystals 10 is that the growth rate tolerance ΔV (=V1−V2) takes a positive value which is equal to greater than the threshold value of 0.005 (mm/min), and this requirement is satisfied when the heat absorption amount Q of the cooler 20 is in the range 36.5 (kW)≦Q≦39 (kW). When the condition for the radius r of the silicon single crystal 10 is applied thereto, the following relation should be established.

r^{2.7}/20500(=36.6)≦Q≦r^{2.7}/19300(=38.9) (6)

On the basis of the expressions (5) and (6) above, it was found that defect-free silicon single crystals 10 was able to be manufactured in a stable manner by designing and arranging the cooler 20 to satisfy the following expression (7) when the heat absorption amount of the cooler 20 was denoted by Q, and the semiconductor single crystal radius was denoted by r.

r^{2.7}/20500≦Q≦r^{2.7}/19300 (7)

When explaining this using FIG. 10 illustrating the relation between the crystal radius r and the heat absorption amount Q, the range defined by the expression (7) above is a range whose upper limit is defined by the line L2u and whose lower limit is defined by the line L2L of FIG. 10. Accordingly, the cooler 20 should be designed and arranged in the CZ furnace 2 such that the heat absorption amount Q is contained in this range.

Once a radius r of a silicon single crystal 10 to be manufactured is determined, the cooler 20 is designed such that the heat absorption amount Q is contained in the range represented by the expression (7) above. When arranging the cooler 20 within the CZ furnace 2, the distance P from the heat shielding plate 8 to the lower end of the cooler 20 (see FIG. 1) and the gap D between the lower edge of the heat shielding plate 8 and the melt surface 5a should be adjusted such that an actual heat absorption amount Q is contained in the range represented by the expression (7) above.

As seen also from FIG. 10, the range represented by the expression (7) contains the range represented by the expression (4) in the first example. It is therefore obvious that the advantageous effects of the first example that the growth rate V can be improved while ensuring the single crystallization are also realized in the range represented by the expression (7).

According to the second example like the first example, it is made possible to instantaneously find optimum design values and optimum arrangement for the cooler 20 without requiring a lot of labor or time, regardless of the housing structure of the CZ furnace 2, configurations of the in-furnace members, and manufacturing conditions. Consequently, the period of time and labor required for designing and arranging the silicon single crystal manufacturing apparatus can be reduced. Further, according to the second example, the cooler 20 can be designed and arranged to ensure stable manufacture of defect-free silicon single crystals.

Although the description of the examples has been made on the assumption that the cooler is of a water cooling type, any cooling medium may be used for the cooler so far as it is able to absorb heat emitted from the silicon single crystal 10 and cool the silicon single crystal 10.

Further, although the description of the examples has been made on the assumption that a silicon single crystal is manufactured as the semiconductor single crystal, the present invention is also applicable to manufacture of compound semiconductors such as gallium arsenide.

What is claimed is:

1. A semiconductor single crystal manufacturing apparatus having a cooler arranged to surround a semiconductor single crystal being pulled from a melt within a furnace, so that the semiconductor single crystal is manufactured by being pulled while being cooled with the cooler,
wherein when a heat absorption amount of the cooler is denoted by Q (kW) and a radius of the semiconductor single crystal is denoted by r (mm), the cooler is designed and arranged so as to satisfy the condition r²/1100≦Q≦r²/400.

2. A semiconductor single crystal manufacturing method for manufacturing a semiconductor single crystal by arranging a cooler to surround a semiconductor single crystal being pulled from a melt within a furnace, and pulling the semiconductor single crystal while cooling the same with the cooler,
wherein when a heat absorption amount of the cooler is denoted by Q (kW) and a radius of the semiconductor single crystal is denoted by r (mm), the cooler is designed and arranged so as to satisfy the condition r²/1100≦Q≦r²/400.

3. A semiconductor single crystal manufacturing apparatus having a cooler arranged to surround a semiconductor single crystal being pulled from a melt within a furnace so that the semiconductor single crystal is manufactured by being pulled while being cooled with the cooler,
wherein when a heat absorption amount of the cooler is denoted by Q (kW) and a radius of the semiconductor single crystal is denoted by r (mm), the cooler is designed and arranged so as to satisfy the condition r^{2.7}/20500≦Q≦r^{2.7}/19300.

4. A semiconductor single crystal manufacturing method for manufacturing a semiconductor single crystal by arranging a cooler within a furnace to surround a semiconductor single crystal being pulled from a melt, and pulling the semiconductor single crystal while cooling the same with the cooler,
wherein when a heat absorption amount of the cooler is denoted by Q (kW) and a radius of the semiconductor single crystal is denoted by r (mm), the cooler is designed and arranged so as to satisfy the condition r^{2.7}/20500≦Q≦r^{2.7}/19300.
